(19) United States
(12) Patent Application Publication
(10) Pub. No.: US 2013/0206201 A1
(43) Pub. Date: Aug. 15, 2013

(54) SOLAR CELL WITH LOW PROFILE POTTING BOX

(71) Applicants: Szu-Han Li, Zhongli City (TW); Tong Hong Fu, Taichung (TW); Wei-Wen Chen, Taichung City (TW)

(72) Inventors: Szu-Han Li, Zhongli City (TW); Tong Hong Fu, Taichung (TW); Wei-Wen Chen, Taichung City (TW)

(73) Assignee: TSMC Solar Ltd., Taichung City (TW)

(21) Appl. No.: 13/370,599

(22) Filed: Feb. 10, 2012

(51) Int. Cl. H01L 31/05; H01L 31/18

(52) U.S. Cl. 136/244; 438/67; 257/E31.113

(57) ABSTRACT

A solar cell assembly provides a solar cell with a reduced size potting ring that retains the conductive contact strips that extend through the solar cell substrate and are coupled to the solar cell circuitry on the front surface of the solar cell substrate. A reduced volume of potting material is required and the solar cells are advantageously packed, shipped and stored in this configuration. Diode connections and power cable connections are made external the potting box once the solar cell assemblies are received at their installation location.

### TECHNICAL FIELD

The disclosure relates to solar cells, and more particularly to solar cell assemblies with reduced profile potting boxes.

### BACKGROUND

Solar cells are photovoltaic components for direct generation of electrical current from sunlight. Due to the growing demand for clean sources of energy, the manufacture of solar cells has expanded dramatically in recent years.

A variety of solar energy collecting modules currently exists. One such module includes a photovoltaic panel that receives solar energy and converts the solar energy directly into electricity. Another such module includes a solar thermal collecting panel which harnesses solar energy for heat. The solar energy collecting modules can have different geometries but generally consist of large, flat solar panels. A high number of such solar panels are manufactured today and must be stored, packaged and shipped en masse because each location that uses such solar panels uses a very high number of solar panels. In addition to the large size of the solar panels themselves, the solar panels typically include junction boxes affixed to their back surfaces. The junction boxes are potted with a potting material and include connections between electrical components such as between the solar panel and power cables and other components. As such, these junction boxes take up considerable space.

One limitation in the growth of solar energy is the space required, and associated cost, for packaging, storing and shipping the completed solar panels to be eventually installed at their desired destination. The junction boxes affixed to the back surfaces, increase the overall size of the solar panels and the space and costs required for packaging, storing and shipping the solar panels.

It would therefore be desirable to reduce the costs associated with packing, storing and shipping the solar energy collecting modules.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIG. 1 is a perspective view showing the back side of a solar cell substrate and FIG. 1A is an enlarged view of the retainer and metal contact strips on the back side shown in FIG. 1 according to various embodiments;

FIG. 2 is a cross-sectional view of a portion of a retainer coupled to a solar cell substrate according to various embodiments;

FIG. 3 is a cross-sectional view showing a number of solar cell substrates with corresponding retainers positioned adjacent one another for packing, shipping or storing according to various embodiments;

FIG. 4 is a perspective view showing a retainer of the disclosure according to various embodiments; and

FIG. 5 shows additional retainer embodiments according to the disclosure.

### DETAILED DESCRIPTION

Solar cells which are alternatively referred to as photovoltaic cells or photoelectric cells, are solid state electrical devices that convert light energy directly into electricity by the photovoltaic effect. A number of solar cells are provided on a substrate that may be referred to as a solar cell substrate, a solar panel, or a solar module. The solar cell substrate is used to capture energy from sunlight. The electrical energy generated from the solar cells is referred to as solar power which is an example of solar energy. Photons in sunlight hit the solar cells and are absorbed by semiconductor materials such as silicon. Negatively charged electrons are knocked loose from their atoms by the photons, causing an electric potential difference. Current starts flowing through the solar cell material to cancel the potential difference and this electricity is captured. The electricity produced by a multitude of solar cells on the solar cell substrate is harnessed and coupled to a power cable. Electrical circuitry on the absorbing surface of the solar cell substrate interconnects the individual solar cells in series and/or parallel by conductive wires or metal ribbons. The conductive wires or metal ribbons are ultimately coupled to a power cable.

The individual solar cells are semiconductor devices typically formed on silicon or other suitable materials. In one embodiment, the silicon is monocrystalline silicon. In one embodiment, the silicon is polycrystalline silicon and is lightly P-doped. According to the lightly P-doped polycrystalline silicon embodiment, the solar cell is made using surface diffusion of N-type dopants into the silicon that forms a P-N junction. Other forms of solar cells are used in other embodiments. Anti-reflection coatings are applied over the solar cells in some embodiments. The anti-reflection coatings increase the amount of light coupled into the individual solar cells. Titanium dioxide and silicon nitride are used as the anti-reflection coatings in various embodiments. With the individual solar cells interconnected together, the harnessed electricity is provided to other sources by coupling to a power cable on the side of the solar cell substrate opposite the absorbing side.

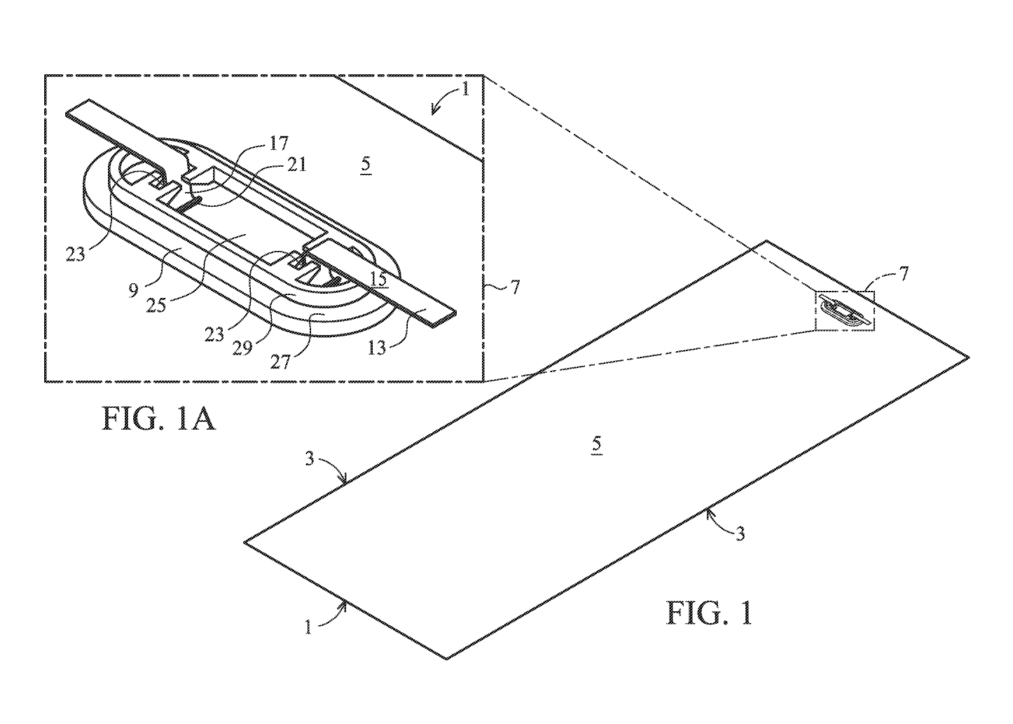

FIG. 1 shows the back side of a solar panel, also referred to as a solar cell substrate. Solar cell substrate 1 includes front surface 3 which is a circuit surface upon which the solar cells (not visible in FIG. 1) are disposed and front surface 3 also includes circuitry coupling the solar cells to one another. Opposed back surface 5 includes conductive metal leads that extend through an opening or openings formed in solar cell substrate 1 and are coupled to the solar cells on front surface 3 of solar cell substrate 1. Solar cell substrate 1 is formed of suitable semiconductor or crystalline materials in one embodiment. According to another embodiment, solar cell substrate 1 is formed of glass. According to other embodiments, other suitable material such as but not limited to stainless steel, molybdenum films, titanium films, and plastic films such as polyimide (“PI”) are used for solar cell substrate 1. Junction assembly 7 is present as indicated in FIG. 1 and it is shown in expanded view in FIG. 1A. FIG. 1 illustrates an embodiment in which back surface 5 of solar cell substrate 1 includes only one junction assembly 7, i.e. no other members are affixed thereon or coupled thereto.

In the embodiment illustrated in FIG. 1, junction assembly 7 is positioned in close proximity to the top of the solar cell substrate 1. In other embodiments, junction assembly 7 is affixed to any of various other locations on opposed back surface 5 of solar cell substrate 1. The embodiment illustrated in FIG. 1 also provides only one junction assembly 7. As will be discussed in further detail below, junction assembly 7 directs the electricity produced by the solar cells on front surface 3 and carried by metal contact strips 13, to other components. In other embodiments, there may be two or more junction assemblies 7 and no other members affixed to opposed back surface 5. In such embodiments, multiple sets of metal contact strips 13 are used to harness and direct the electricity produced by the solar cells on front surface 3 of solar cell substrate 1.

FIG. 1A illustrates junction assembly 7 in an expanded view. Junction assembly 7 includes a single retainer 9 and a plurality of metal contact strips 13 that extend through solar cell substrate 1 and are positioned for being coupled to power cables and for having a diode coupled between the two metal contact strips 13. Retainer 9 is a single piece in the illustrated embodiment and may be formed of metal, plastic, or other suitable alloys or polymers. Retainer 9 takes on other shapes in other embodiments. In other embodiments, retainer 9 includes more than one single piece. Retainer 9 secures metal contact strips 13 in position and allows for separate connection to power cables and diodes external to retainer 9. Metal contact strips 13 extend through and are secured by retainer 9. More particularly, metal contact strips 13 include respective base portions 17 that extend through corresponding openings 21 formed in solar cell substrate 1. Metal contact strips 13 also include segments 15 that are disposed orthogonal to base portion 17 and parallel to back surface 5. Metal contact strips 13 may be formed of aluminum, copper, gold, or other suitable metal materials. Metal contact strips 13 are generally ribbon-shaped in the illustrated embodiment but may take on other shapes and configurations in other exemplary embodiments. Although two metal contact strips 13 are illustrated in the embodiment of FIGS. 1 and 1A, additional metal contact strips may be utilized and retained by retainer 9, in other embodiments.

Retainer 9 includes a low profile, i.e. retainer 9 includes a thickness less than the distance between parallel segments 15 of metal contact strip 13 and back surface 5, in the illustrated embodiment of FIG. 1A. Stated alternatively, parallel segments 15 of the metal contact strip 13 are disposed above retainer 9 with respect to back surface 5. In other embodiments, retainer 9 includes a thickness about the same as the distance between parallel segments 15 of metal contact strip 13 and back surface 5. In this embodiment, parallel segments 15 essentially rest upon a top surface of retainer 9.

In the illustrated embodiment of FIG. 1A, retainer 9 has a generally oval footprint, is annular in shape and includes void portions such as central void area 25. Retainer 9 also includes slots 23 which receive base portions 17 of metal contact strips 13 therein. According to other embodiments in which metal contact strips 13 have other configurations, retainer 9 will include different and correspondingly shaped openings that receive and secure metal contact strips 13. Retainer 9 includes base portion 27 and central portion 29. Base portion 27 includes a greater circumference than central portion 29. Central portion 29 includes central void area 25 for receiving the adhesive potting material. In one embodiment, the footprint area of retainer 9, defined by base portion 29, may be about 10 cm² or less. In various embodiments, the footprint area of retainer 9 is less than 7 cm² but other sizes may be used in other exemplary embodiments.

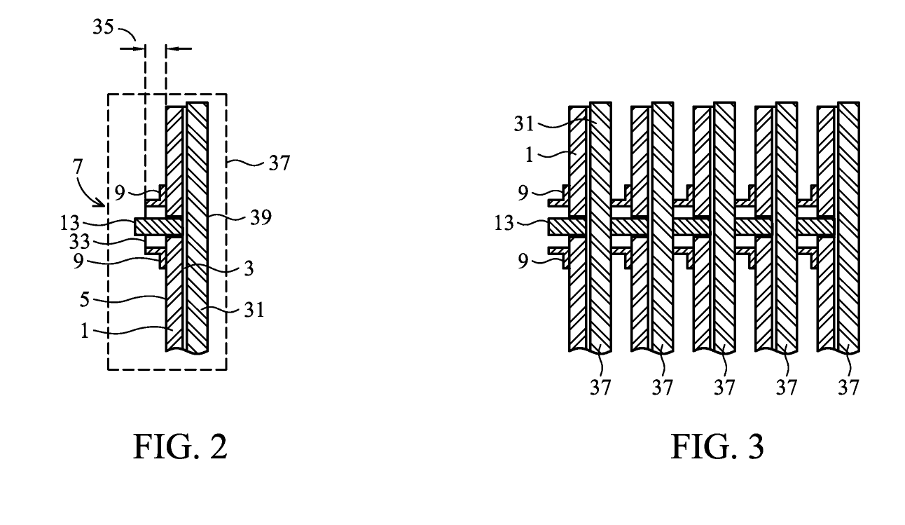

According to the embodiment illustrated in FIGS. 1 and 1A, the solar cell assembly is configured for packing, storing and shipping. Power cables, diodes and other electronic components are not included in this configuration. This reduces the space between two solar cell substrates 1 in a shipping container thereby minimizing the overall space occupied by solar cell substrate 1. The power cables, diodes and other electronic components can be densely packaged, stored, and shipped in a different container. FIG. 2 is a cross-sectional view of a portion of a retainer coupled to a solar cell substrate according to various embodiments. In FIG. 2, solar cell substrate 1 combines with cover substrate 31 and junction assembly 7 to produce solar cell assembly 37. Solar cell substrate 1 includes front surface 3 which includes solar cells and circuitry. Cover substrate 31 may be formed of glass or other suitable transparent materials that protect and cover the solar cells formed on front surface 3. In some embodiments, additional films may be disposed between front surface 3 of solar cell substrate 1 and cover substrate 31. Various films such as ethylene-vinyl acetate (“EVA”), polyvinyl butyral (“PVB”), low density polyethylene (“LDPE”) or ionomer films may be formed as an encapsulant on front surface 3 and thus between solar cell substrate 1 and cover substrate 31. In some embodiments, cover substrate 31 may have an ethylene tetraflouroethylene (“ETFE”) plastic film placed on outer surface 39 to serve as a cover. Metal contact strips 13 extend from and are electrically coupled to the array of solar cells formed on front surface 3. Metal contact strips 13 also extend through solar cell substrate 1 and past back surface 5. In the illustrated embodiment, retainer 9 includes a profile, i.e. a thickness 35, less than the height of metal contact strips 13. In other embodiments, thickness 35 is substantially the same as the height of metal contact strips 13. In one exemplary embodiment, thickness 35 is 7 mm or less. In other embodiments, other thicknesses are used.

Potting refers to the process of filling a complete electronic assembly such as junction assembly 7, with a solid compound for resistance to shock and vibration and for exclusion of moisture and corrosive agents. Retainer 9 includes potting volume 33. Potting material fills void areas of retainer 9 which may alternatively be referred as a potting box or potting ring. The potting material may be various glues or other suitable adhesive potting materials. The adhesive potting material that fills potting volume 33 may be an epoxy resin, silicone, polyurethane, or butylol or various other suitable materials in various embodiments. Various methods for introducing the potting material into potting volume 33 are used. The adhesive potting material secures retainer 9 to back surface 5 of solar cell substrate 1. The adhesive potting material also secures metal contact strips 13 in place within slots 23 and provides a waterproof seal that excludes moisture and corrosive agents.

FIG. 3 is a cross-sectional view showing five solar cell assemblies 37 positioned adjacent one another such as for packing, shipping or storing. In the illustrated embodiment, adjacent solar cell assemblies 37 are tightly packed. Metal contact strips 13 and retainer 9 of one solar cell assembly 37 contact cover substrate 31 of the adjacent solar cell assembly 37 to minimize the volume occupied by the solar cell assemblies 37 for packing, shipping or storing. In the illustrated embodiment, metal contact strips 13 include the same height as retainer 9. According to this embodiment, adjacent solar cell assemblies 37 can be packed most tightly together. In the illustrated embodiment of FIG. 3, parallel segments 15 (see FIG. 1A) of metal contact strips 13 are tightly secured between retainer 9 and the adjacent solar cell assembly 37. This prevents bending or other damaging during packaging and shipping.

The solar cell assemblies 37 may be packaged and shipped using an economy of space. According to the disclosure, solar cell assembly 37 is packed, shipped or stored without connection to power cables and without connection to diodes or any further components. In some embodiments, when the solar cell assembly is ready for packing, storing and shipping, retainer 9 includes only metal contact strips 13 and potting material. In other embodiments the metal contact strips 13 may additionally include attached soldering terminals. Packing means that a plurality of solar cell assemblies 37, which may be arranged according to the configuration shown in FIG. 3, may be batched, bound, braced, bundled, fastened, gathered, arranged, loaded, packaged, stored, stowed, warehoused or otherwise made ready for storage or transport. In its illustrated configuration, solar cell assembly 37 is then delivered to its installation destination. In one embodiment, the plurality of solar cell assemblies 37 are packed in a crate and shipped to their delivery destination. Other packing devices may be used in other embodiments. At the delivery destination, power cables and diodes may be coupled to metal contact strips 13 as desired. Further components may also be coupled to metal contact strips 13 so that the electrical power generated by the solar cells on the front side of solar cell substrate 1 can be provided to further components. The connections are made external to retainer 9, in various exemplary embodiments. In one embodiment, the power cables may be soldered to metal contact strips 13. In another embodiment, power cables may be coupled to metal contact strips 13 using various mechanical clip members. Various other components may be used to couple the power cables to metal contact strips 13 in other embodiments. Soldering or other suitable connection methods are used to join metal contact strips 13 to diodes and other electrical components. The coupling between metal contact strips 13 and power cables is made external to retainer 9 but the other components such as diodes, may be retained or secured by other features added to the solar cell assembly after packing and shipping.

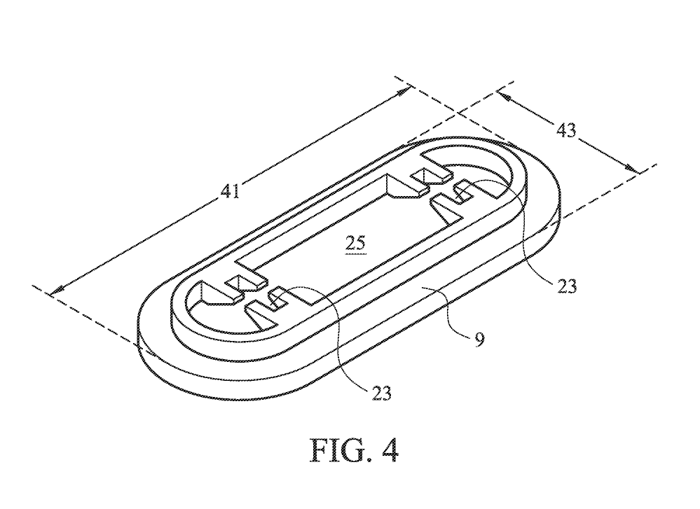

FIG. 4 is a perspective isolation view of the potting box, i.e., retainer 9, according to some embodiments. Retainer 9 includes central void area 25. Slots 23 are shown more clearly and in more detail, in FIG. 4. Slots 23 receive metal contact strips 13 as in the previous illustrations. In other embodiments, metal contact strips 13 may have other shapes and retainer 9 will include an appropriately sized and shaped slot, cavity or other opening to receive the variously shaped metal contact strips 13. In some embodiments, the slots may represent a single opening extending through a solid portion of retainer 9. Retainer 9 is advantageously formed to include a compact size thereby realizing a savings used in the potting material required to fill the void areas in retainer 9, i.e. potting volume 33 shown in FIG. 2. In one exemplary embodiment, retainer 9 may include a length 41 of about 2.5-3.5 centimeters and a width 43 of about 1.5-2.5 centimeters which is significantly less than conventional junction boxes. Conventional junction boxes are larger and are sized to retain internal components such as diodes that couple metal contact strips 13, and internal connections between metal contact strips 13 and power cables.

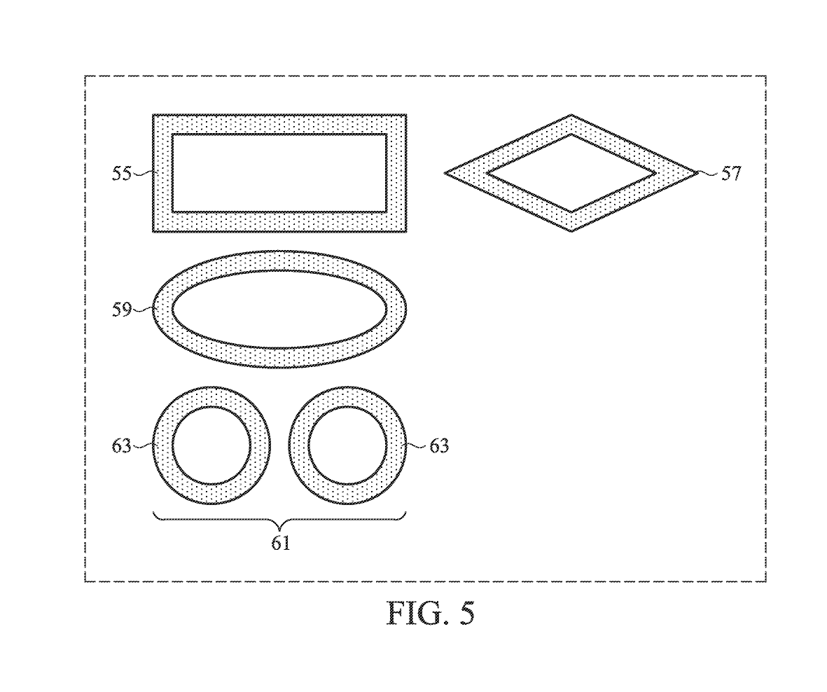

FIG. 5 shows additional shapes for different embodiments of retainer 9. In addition to the generally oval shape shown in FIGS. 1A and 4, FIG. 5 illustrates rectangle 55, diamond-shape 57, further oval 59 and two member arrangement 61 including two rings 63. Note that FIG. 5 illustrates the general shapes of the retainer assembly and does not show further details of the retainer. It should be understood, however, that according to each embodiment, the respective retainer will include slots, recesses or other suitable openings to receive and secure metal leads such as metal contact strips 13 that extend through the solar cell substrate and terminate outside back surface 5. For each of the illustrated retainer shape embodiments shown in FIG. 5, the retainer may include a base portion that defines the footprint of the retainer member, and a central portion that has a circumference less than the circumstance of the base portion in some embodiments. Other configurations are used in other embodiments. According to the two-member 61 embodiment, an even greater reduction in the use of potting material is achieved. In this two-member embodiment, each ring 63 receives one metal contact strip 13 or other conductive lead. More particularly, each ring 63 includes a slot or opening for receiving a respective one of the metal contact strips.

According to one aspect, the disclosure provides a solar panel arrangement. The solar panel arrangement includes a solar panel including a solar cell substrate. The solar cell substrate includes a circuit surface with an array of solar cells thereon and an opposing back surface including a retainer member disposed thereon; metal contact strips electrically coupled to the array of solar cells and extending through the solar cell substrate and through the retainer member and including segments disposed over the retainer member. The segments disposed above the retainer member are spaced from the back surface by a first distance and the retainer member has a thickness no greater than the first distance.

According to one aspect, the disclosure provides a solar panel assembly configured for shipping, packing and storing. The solar panel assembly includes: a solar panel having a solar cell substrate and a cover substrate; and metal contact strips electrically coupled to an array of solar cells on a circuit surface of the solar cell substrate. Each of the metal contact strips includes a base segment extending through the solar cell substrate and a contact segment coupled to the base segment and spaced from the back surface by a first distance. The metal contact strips are retained in position by a retainer member having a thickness no greater than the first distance and the contact segments are configured to be coupled to power cables external the retainer member. The back surface includes only the retainer member disposed thereon.

Further provided is a method for assembling a solar cell assembly. The method includes: providing a solar panel comprising a solar cell substrate and a cover substrate, the solar panel including electrical contact strips electrically coupled to an array of solar cells on a circuit surface of the solar cell substrate, extending through the solar cell substrate and including segments disposed outside an opposed back surface of the solar cell substrate, the opposed back surface having a single retainer thereon, the retainer comprising a solid member and receiving the segments extending therethrough, and coupled to the opposed back surface by an adhesive potting material. The method further comprises packing a plurality of the solar panels with the single retainer and no electrical components joined to the segments; and after the packing, joining power cables to the solar panel by coupling ends of the power cables to the segments external to the retainer member.

The preceding merely illustrates the principles of the disclosure. It will thus be appreciated that those skilled in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those skilled in the art without departing from the scope and range of equivalents of the disclosure.

What is claimed is:

1. A solar panel arrangement comprising:
a solar panel including a solar cell substrate;
the solar cell substrate including a circuit surface with an array of solar cells thereon and an opposed back surface including a retainer member disposed thereon; and
metal contact strips electrically coupled to the array of solar cells and extending through the solar cell substrate and through the retainer member, each of the metal contact strips including a segment disposed over the retainer member and spaced from the back surface by a first distance, the retainer member having a thickness no greater than the first distance.

2. The solar panel arrangement as in claim 1, wherein the solar panel further comprises a cover substrate covering the circuit surface and the retainer member is joined to the opposed back surface by an adhesive potting material.

3. The solar panel arrangement as in claim 2, wherein the adhesive potting material comprises one of an epoxy resin, silicone, polyurethane and butylol.

4. The solar panel arrangement as in claim 1, wherein the retainer member is formed of one of plastic and metal and includes a footprint having an area less than about 7 cm² and a thickness less than about 7 mm.

5. The solar panel arrangement as in claim 1, wherein the solar panel further comprises a cover substrate covering the circuit surface and the retainer member has a shape being one of elliptical, rectangular, annular, ring-shaped and diamond-shaped, and includes a central void area.

6. The solar panel arrangement as in claim 1, further comprising power cables coupled to the segments external to the retainer member.

7. The solar panel arrangement as in claim 1, wherein the segments extend parallel to the back surface and the metal contact strips each include an orthogonal segment extending through solar cell substrate and the retainer member and retained in a corresponding slot in the retainer member, and wherein the retainer member includes a base portion contacting the opposed back surface and an upper portion having a circumference less than a base circumference of the base portion.

8. The solar panel arrangement as in claim 7, further comprising at least one diode coupling the segments and disposed external to the retainer member.

9. The solar panel arrangement as in claim 1, further comprising:
a further retainer member disposed on the opposed back surface; and
further metal contact strips electrically coupled to the array of solar cells and extending through the solar cell substrate and through the further retainer member.

10. A solar panel assembly configured for shipping, packing and storing, the solar panel assembly comprising:
a solar panel having a solar cell substrate and a cover substrate;
metal contact strips electrically coupled to an array of solar cells on a circuit surface of the solar cell substrate, each of the metal contact strips including a base segment extending through the solar cell substrate and a contact segment coupled to the base segment and spaced from an opposed back surface of the solar cell substrate by a first distance;
wherein the metal contact strips are retained in position by a retainer member having a thickness no greater than the first distance and the contact segments are configured to be coupled to power cables external the retainer member; and
the back surface includes only the retainer member disposed thereon.

11. The solar panel assembly as in claim 10, wherein the base segments are orthogonal to the contact segments, extend through the retainer member and are retained in a corresponding recess of the retainer member, and the retainer member is joined to the back surface by an adhesive potting material comprising one of an epoxy resin, silicone, polyurethane and butylol.

12. The solar panel assembly as in claim 10, wherein:
the cover substrate is formed of glass and is disposed facing the circuit surface of the solar cell substrate;
the retainer member is a unitary piece having a shape being one of elliptical, rectangular, annular, ring-shaped and diamond-shaped and includes a central void area; and
the contact segments are on the back surface side of the solar cell substrate and are substantially parallel to the back surface.

13. The solar panel assembly as in claim 11, wherein the retainer member comprises two rings, each of the base segments extending through and received in a slot within a corresponding one of the rings.

14. The solar panel assembly as in claim 10, wherein the retainer member is a unitary piece formed of one of plastic and metal and includes a thickness less than about 7 mm, a base portion having a footprint with an area less than about 7 cm² and an upper portion having a circumference less than a base circumference of the base portion.

15. A method for assembling a solar cell, the method comprising:
providing a plurality of solar panels, each said solar panel including a solar cell substrate and a cover substrate, the solar panel including electrical contact strips electrically coupled to an array of solar cells on a circuit surface of the solar cell substrate, extending through the solar cell substrate and including contact segments extending past an opposed back surface of the solar cell substrate, the opposed back surface having a retainer member thereon, the retainer member receiving the contact segments extending therethrough, and the retainer member coupled to the opposed back surface by an adhesive potting material;
packing the plurality of solar panels with the corresponding retainer members and no further electrical components joined to the contact segments; and
after the packing, joining power cables to at least one of the solar panels by coupling ends of the power cables to the contact segments external to the retainer member.

16. The method as in claim 15, wherein the packing comprises disposing the plurality of solar panels adjacent one another in a crate, and further comprising delivering the packed plurality of the solar panels to an installation location and removing the plurality of the solar panels from the crate, prior to the joining.

17. The method as in claim 15, further comprising, after the packing, coupling a diode to the contact segments external to the retainer member on at least one of the solar panels.

18. The method as in claim 15, wherein the electrical contact strips each include a base segment orthogonal to the corresponding back surface and received in a cavity of the corresponding retainer member and wherein the contact segments are parallel to the corresponding back surface and spaced from the corresponding back surface by a distance and the corresponding retainer member includes a thickness no greater than the distance.

19. The method as in claim 15, wherein, for each of the solar panels,
the electrical contact strips each include a base segment orthogonal to the back surface and received in a cavity of the retainer member,
the contact segments are parallel to the back surface,
the retainer member is disposed between the contact segments and the back surface and includes a base portion contacting the back surface and a central portion having a circumference less than a base circumference of the base portion, and
the providing includes introducing the adhesive potting material into the central portion.

20. The method as in claim 15, wherein the providing includes, for each of the solar panels, disposing the retainer member against the back surface of the solar cell substrate, the retainer including a footprint having an area less than about 7 cm² and a thickness less than about 7 mm, and joining the retainer to the back surface with the electrical contact strips extending therethrough by filling the retainer with the adhesive potting material.
